(19) United States
(12) Patent Application Publication
(10) Pub. No.: US 2007/0054487 A1
(43) Pub. Date: Mar. 8, 2007

(54) ATOMIC LAYER DEPOSITION PROCESSES FOR RUTHENIUM MATERIALS

(75) Inventors: PAUL MA, Sunnyvale, CA (US); KAVITA SHAH, Sunnyvale, CA (US); DIEN-YEH WU, San Jose, CA (US); SESHADRI GANGULI, Sunnyvale, CA (US); CHRISTOPHE MARCADAL, Santa Clara, CA (US); FREDERICK C. WU, Cupertino, CA (US); SCHUBERT S. CHU, San Francisco, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/470,466

(22) Filed: Sep. 6, 2006

Related U.S. Application Data
(60) Provisional application No. 60/714,580, filed on Sep. 6, 2005.

(51) Int. Cl. H01L 21/44

(52) U.S. Cl. 438/681; 438/686; 438/650

(57) ABSTRACT

Embodiments of the invention provide a method for depositing ruthenium materials on a substrate by various vapor deposition processes, such as atomic layer deposition (ALD) and plasma-enhanced ALD (PE-ALD). In one aspect, the process has little or no initiation delay and maintains a fast deposition rate while forming a ruthenium material. The ruthenium material may be deposited with good step coverage, strong adhesion, and contains a low carbon concentration for high electrical conductivity. The method for depositing the ruthenium material on a substrate generally includes sequentially exposing the substrate to a pyrrolyl ruthenium precursor and a reagent during the ALD process. The pyrrolyl ruthenium precursor contains ruthenium and at least one pyrrolyl ligand. In some examples, the reagent may contain a plasma of ammonia, nitrogen, or hydrogen during a PE-ALD process. In other examples, a reducing gas may be used during a thermal ALD process.

### CROSS-REFERENCE TO RELATED APPLICATIONS

This application claims benefit of U.S. Ser. No. 60/714,580 (APPM/010314L), filed Sep. 6, 2005, which is herein incorporated by reference in its entirety.

### BACKGROUND OF THE INVENTION

1. Field of the Invention

Embodiments of the invention generally relate to a method for depositing a ruthenium material, and more particularly to a method for forming a ruthenium material by an atomic layer deposition process.

2. Description of the Related Art

Sub-quarter micron, multi-level metallization is one of the key technologies for the next generation of very large scale integration (VLSI) and ultra large scale integration (ULSI) semiconductor devices. The multilevel interconnects that lie at the heart of this technology require the filling of contacts, vias, lines, and other features formed in high aspect ratio apertures. Reliable formation of these features is important to the success of both VLSI and ULSI as well as to the continued effort to increase density and quality on individual substrates and dies.

As circuit densities increase, the widths of contacts, vias, lines and other features, as well as the dielectric materials between them may decrease to less than 250 nm, whereas the thickness of the dielectric layers remains substantially constant, with the result that the aspect ratios for the features, i.e., their height divided by width, increases. Many conventional deposition processes have difficulty filling structures where the aspect ratio exceeds 6.1, and particularly where the aspect ratio exceeds 10:1. As such, there is a great amount of ongoing effort being directed at the formation of void-free, nanometer-sized structures having aspect ratios wherein the ratio of feature height to feature width is 6:1 or higher.

Additionally, as the feature widths decrease, the device current typically remains constant or increases, which results in an increased current density for such feature. Elemental aluminum and aluminum alloys have been the traditional metals used to form vias and lines in semiconductor devices because aluminum has a perceived low electrical resistivity, superior adhesion to most dielectric materials, ease of patterning, and the ability to obtain aluminum in a highly pure form. However, aluminum has a higher electrical resistivity than other more conductive metals such as copper. Aluminum can also suffer from electromigration leading to the formation of voids within the conductor.

Copper and copper alloys have lower resistivities than aluminum, as well as a significantly higher electromigration resistance compared to aluminum. These characteristics are important for supporting the higher current densities experienced at high levels of integration and increased device speed. Copper also has good thermal conductivity. Therefore, copper is becoming a choice metal for filling sub-quarter micron, high aspect ratio contacts (HARC) as interconnect features on semiconductor substrates.

A thin film of a noble metal such as, for example, palladium, platinum, cobalt, nickel and rhodium, among others may be used as an underlayer for copper containing vias and lines. Such noble metals, which are resistant to corrosion and oxidation, may provide a smooth surface upon which a copper seed layer is subsequently formed during a deposition process, such as an electroless deposition process or an electrochemical plating (ECP) process.

The noble metal is typically deposited using a chemical vapor deposition (CVD) process or a physical vapor deposition (PVD) process. Unfortunately, a noble metal layer deposited on high aspect ratio interconnect features by a CVD process or a PVD process generally has poor step coverage (e.g., deposition of a non-continuous material layer). The poor step coverage of the noble metal material layer may cause the subsequent copper seed layer to be non-uniform.

Atomic layer deposition (ALD) processes generally provide high step coverage for deposition of transition metals, such as titanium, tungsten, and tantalum but has not been used as successfully for deposition of noble metals. Ruthenium materials have been deposited by ALD techniques that use various ruthenocene precursors (ruthenium-containing metallocenes), such as bis(ethylcyclopentadienyl) ruthenium, bis(cyclopentadienyl) ruthenium, and bis(pentamethylcyclopentadienyl) ruthenium. However, these aforementioned ruthenocene precursors generally require particular process conditions, such as hydroxylated (—OH) or electron-rich (e.g., metallic) surfaces and adsorption temperatures of above 400° C. The ALD processes that use these ruthenocene precursors usually suffer with an initiation delay and a rather slow deposition rate, such as less than 0.2 Å/cycle. The ruthenium materials formed from these ruthenocene precursors usually have an increased electrical resistivity due to a high carbon concentration and an unevenness of the layer. Also, the ruthenocene derived ruthenium materials have a tendency to fail a tape test due to low adhesion properties on dielectric materials.

Therefore, a need exists for a process that may be used to deposit ruthenium materials on a substrate, wherein the process has little or no initiation delay and has a fast deposition rate while forming a ruthenium material with good step coverage, strong adhesion, and low carbon concentration.

### SUMMARY OF THE INVENTION

A method for forming a ruthenium material within a high aspect ratio contact (HARC) or other interconnect feature is provided by an atomic layer deposition (ALD) process. In one embodiment of the invention, a method for forming a ruthenium material on a substrate includes positioning a substrate within a process chamber and exposing the substrate sequentially to a pyrrolyl ruthenium precursor and a reagent during an ALD process while forming a ruthenium material on the substrate. The pyrrolyl ruthenium precursor contains ruthenium and at least one pyrrolyl ligand with the chemical formula of: 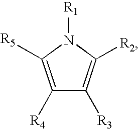
wherein R₁, R₂, R₃, R₄, and R₅ are each independently absent or selected from hydrogen or an organic group, such as methyl, ethyl, propyl, butyl, amyl, derivatives thereof, or combinations thereof. In one example, R₁ may be absent and each of R₂, R₃, R₄, and R₅ may be either a hydrogen group or a methyl group. In another example, R₁ may be absent, each of R₂ and R₅ may be a methyl group or an ethyl group, and each of R₃ and R₄ may be a hydrogen group.

The method further provides that the pyrrolyl ruthenium precursor may contain a first pyrrolyl ligand and a second pyrrolyl ligand, such that the first pyrrolyl ligand may be the same as or different than the second pyrrolyl ligand. Alternatively, the pyrrolyl ruthenium precursor may contain a first pyrrolyl ligand and a dienyl ligand. For example, the pyrrolyl ruthenium precursor may be a pentadienyl pyrrolyl ruthenium precursor, a cyclopentadienyl pyrrolyl ruthenium precursor, an alkylpentadienyl pyrrolyl ruthenium precursor, or an alkylcyclopentadienyl pyrrolyl ruthenium precursor. Therefore, the method provides that the pyrrolyl ruthenium precursor may be an alkyl pyrrolyl ruthenium precursor, a bis(pyrrolyl) ruthenium precursor, a dienyl pyrrolyl ruthenium precursor, or derivatives thereof. Some exemplary pyrrolyl ruthenium precursors include bis(tetramethylpyrrolyl) ruthenium, bis(2,5-dimethylpyrrolyl) ruthenium, bis(2,5-diethylpyrrolyl) ruthenium, bis(tetraethylpyrrolyl) ruthenium pentadienyl tetramethylpyrrolyl ruthenium, pentadienyl 2,5-dimethylpyrrolyl ruthenium, pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium, methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium and derivatives thereof.

In another embodiment, a method for forming a ruthenium material on a substrate includes positioning a substrate within a process chamber and exposing the substrate sequentially to an active reagent and a pyrrolyl ruthenium precursor during a plasma-enhanced ALD (PE-ALD) process. Although a plasma may be ignited during any time during the PE-ALD process, preferably, the plasma is ignited while the reagent is exposed to the substrate. The plasma activates the reagent to form an active reagent. Examples of an active reagent include an ammonia plasma, a nitrogen plasma, and a hydrogen plasma. One embodiment of the PE-ALD process provides that the plasma is generated externally from the process chamber, such as by a remote plasma generator (RPS) system. However, a preferred embodiment of the PE-ALD process provides that the plasma is generated in situ by a plasma capable process chamber utilizing a microwave (MW) frequency generator, or preferably, a radio frequency (RF) generator. In an alternative embodiment, a method for forming a ruthenium material on a substrate includes positioning a substrate within a process chamber and exposing the substrate sequentially to a reagent and a pyrrolyl ruthenium precursor during a thermal-ALD process.

The ruthenium material may be deposited on a barrier layer (e.g., copper barrier) or dielectric material (e.g., low-k) disposed on the substrate during the various ALD processes described herein. The barrier layer may contain a material that includes tantalum, tantalum nitride, tantalum silicon nitride, titanium, titanium nitride titanium silicon nitride, tungsten, or tungsten nitride. In one example, the ruthenium material is deposited on a tantalum nitride material previously formed by an ALD process or a PVD process. The dielectric material may include silicon dioxide, silicon nitride, silicon oxynitride, carbon-doped silicon oxides or a SiOₓC_{y} material.

A conductive metal is usually deposited on the ruthenium material. The conductive material may be copper, tungsten, aluminum, alloys thereof, or combinations thereof. In one aspect, the conductive metal may be formed as one layer during a single deposition process. In another aspect, the conductive metal may be formed as multiple layers, each deposited by an independent deposition process. In one embodiment, a seed layer is deposited on the ruthenium material by an initial deposition process and a bulk layer is subsequently deposited thereon by another deposition process. In one example, a copper seed layer is formed by an electroless deposition process, an electroplating (ECP) process, or a PVD process, and a copper bulk layer is formed by an electroless deposition process, an ECP process, or a CVD process. In another example, a tungsten seed layer is formed by an ALD process or a PVD process, and a tungsten bulk layer is formed by a CVD process or a PVD process.

### BRIEF DESCRIPTION OF THE DRAWINGS

So that the manner in which the above recited features of the invention are attained and can be understood in detail, a more particular description of the invention briefly summarized above, may be had by reference to the embodiments thereof, which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C illustrate schematic cross-sectional views of a substrate during an integrated circuit fabrication process; and

FIGS. 2A-2C illustrate schematic cross-sectional views of another substrate during an integrated circuit fabrication process.

### DETAILED DESCRIPTION OF THE PREFERRED EMBODIMENT

Embodiments of the invention provide a method for depositing ruthenium materials on a substrate by various vapor deposition processes, such as atomic layer deposition (ALD) and plasma-enhanced ALD (PE-ALD). In one aspect, the process may have little or no initiation delay and maintain a fast deposition rate while forming a ruthenium material. The ruthenium material may be deposited with good step coverage, strong adhesion, and contain a low carbon concentration for high electrical conductivity.

In order to overcome the shortcomings of the prior art, the method for forming the ruthenium material on a substrate includes exposing the substrate sequentially to a reagent and a pyrrolyl ruthenium precursor during an ALD process. The pyrrolyl ruthenium precursor contains ruthenium and at least one pyrrolyl ligand. The pyrrolyl ligand provides the pyrrolyl ruthenium precursor advantages over previous ruthenium precursors (e.g., ruthenocene and derivatives thereof) during an ALD process. For example, the pyrrolyl ligand is more thermodynamically stable than many ligands, as well as forms a very volatile chemical precursor. The pyrrolyl ligand may have the chemical formula of: 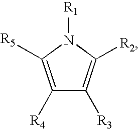
wherein R₁, R₂, R₃, R₄, and R₅ are each independently absent, or selected from hydrogen, methyl, ethyl, propyl, butyl, amyl, derivatives thereof, or combinations thereof. In one example, R₁ may be absent and R₂, R₃, R₄, and R₅ may be each independently hydrogen or methyl. In another example, R₁ may be absent and R₂ and R₅ may be methyl or ethyl, and R₃ and R₄ may be each hydrogen.

In one embodiment, a ruthenium material may be formed during a PE-ALD process containing a constant flow of a reagent gas while providing sequential pulses of a ruthenium precursor and a plasma. In another embodiment, a ruthenium material may be formed during another PE-ALD process that provides sequential pulses of a ruthenium precursor and a reagent plasma. In both of these embodiments, the reagent is generally ionized during the process. Also, the PE-ALD process provides that the plasma may be generated externally from the process chamber, such as by a remote plasma generator (RPS) system, or preferably, the plasma may be generated in situ a plasma capable ALD process chamber. During PE-ALD processes, a plasma may be generated from a microwave (MW) frequency generator or a radio frequency (RF) generator. In a preferred example, an in situ plasma is generated by an RF generator. In another embodiment, a ruthenium material may be formed during a thermal ALD process that provides sequential pulses of a ruthenium precursor and a reagent.

An ALD process chamber used during embodiments described herein is available from Applied Materials, Inc., located in Santa Clara, Calif. A detailed description of an ALD process chamber may be found in commonly assigned U.S. Pat. Nos. 6,916,398 and 6,878,206, and commonly assigned, co-pending U.S. Ser. No. 10/281,079, entitled “Gas Delivery Apparatus for Atomic Layer Deposition,” filed on Oct. 25, 2002, and published as U.S. Pub. No. 2003-0121608, which are hereby incorporated by reference in their entirety. In another embodiment, a chamber configured to operate in both an ALD mode, as well as a conventional CVD mode may be used to deposit ruthenium materials, and is described in commonly assigned and co-pending U.S. Ser. No. 10/712,690, entitled “Apparatus and Method for Hybrid Chemical Processing,” filed on Nov. 13, 2003, and published as U.S. Pub. No. 2004-0144311, which is incorporated herein by reference in its entirety.

The ALD process provides that the process chamber may be pressurized at a pressure within a range from about 0.1 Torr to about 80 Torr, preferably from about 0.5 Torr to about 10 Torr, and more preferably, from about 1 Torr to about 5 Torr. Also, the chamber or the substrate may be heated to a temperature of less than about 500° C., preferably, within a range from about 10° C. to about 450° C., and more preferably, from about 150° C. to about 400° C., for example, about 300° C. During PE-ALD processes, a plasma may be ignited within the process chamber for an in situ plasma process, or alternatively, may be formed by an external source, such as a remote plasma generator (RPS) system. A plasma may be generated by an MW generator, but preferably by an RF generator. The RF generator may be set at a frequency of about 1.6 GHz or less, such as within a range from about 100 KHz to about 1.6 GHz. Some example include the RF generator set at a frequency of about 1.6 MHz or about 60 MHz. In one example, an RF generator, with a frequency of 13.56 MHz, may be set to have a power output within a range from about 100 watts to about 1,000 watts, preferably, from about 250 watts to about 600 watts, and more preferably, from about 300 watts to about 500 watts. In another example, an RF generator, with a frequency of 400 KHz, may be set to have a power output within a range from about 200 watts to about 2,000 watts preferably, from about 500 watts to about 1,500 watts. A surface of substrate may be exposed to a plasma having a power per surface area value within a range from about 0.01 watts/cm² to about 10.0 watts/cm², preferably, from about 0.05 watts/cm² to about 6.0 watts/cm².

The substrate may be, for example, a silicon substrate having an interconnect pattern defined in one or more dielectric material layers formed thereon. In one example, the substrate contains a barrier layer surface, while in another example, the substrate contains a dielectric surface. The process chamber conditions, such as the temperature and pressure, are adjusted to enhance the adsorption of the process gases on the substrate so as to facilitate the reaction of the pyrrolyl ruthenium precursors and the reagent gas.

In one embodiment, the substrate may be exposed to a reagent gas throughout the whole ALD cycle. The substrate may be exposed to a ruthenium precursor gas formed by passing a carrier gas (e.g., nitrogen or argon) through an ampoule of a ruthenium precursor. The ampoule may be heated depending on the ruthenium precursor used during the process. In one example, an ampoule containing methylcyclopentadienyl pyrrolyl ruthenium ((MeCp)(Py)Ru) may be heated to a temperature within a range from about 60° C. to about 100° C., such as 80° C. The ruthenium precursor gas usually has a flow rate within a range from about 100 sccm to about 2,000 sccm, preferably, from about 200 sccm to about 1,000 sccm, and more preferably, from about 300 sccm to about 700 sccm, for example, about 500 sccm. The ruthenium precursor gas and the reagent gas may be combined to form a deposition gas. A reagent gas usually has a flow rate within a range from about 100 sccm to about 3,000 sccm, preferably, from about 200 sccm to about 2,000 sccm, and more preferably, from about 500 sccm to about 1,500 sccm. In one example, ammonia is used as a reagent gas with a flow rate of about 1,500 sccm. The substrate may be exposed to the ruthenium precursor gas or the deposition gas containing the ruthenium precursor and the reagent gas for a time period within a range from about 0.1 seconds to about 8 seconds, preferably, from about 1 second to about 5 seconds, and more preferably, from about 2 seconds to about 4 seconds. The flow of the ruthenium precursor gas may be stopped once the ruthenium precursor is adsorbed on the substrate. The ruthenium precursor may be a discontinuous layer, continuous layer, or even multiple layers.

The substrate or chamber may be exposed to a purge step after stopping the flow of the ruthenium precursor gas. The flow rate of the reagent gas may be maintained or adjusted from the previous step during the purge step. In one example, the flow of the reagent gas is maintained from the previous step. Optionally, a purge gas may be administered into the process chamber having a flow rate within a range from about 100 sccm to about 2,000 sccm, preferably, from about 200 sccm to about 1,000 sccm, and more preferably, from about 300 sccm to about 700 sccm, for example, about 500 sccm. The purge step removes excess ruthenium precursor and other contaminants that may be within the process chamber. The purge step may be conducted for a time period within a range from about 0.1 seconds to about 8 seconds, preferably, from about 1 second to about 5 seconds, and more preferably, from about 2 seconds to about 4 seconds. The carrier gas, the purge gas and the process gas may contain nitrogen, hydrogen, argon, neon, helium, or combinations thereof. In one example, the carrier gas contains nitrogen.

Thereafter, the flow of the reagent gas may be maintained or adjusted before igniting a plasma. The substrate may be exposed to the plasma for a time period within a range from about 0.1 seconds to about 20 seconds, preferably, from about 1 second to about 10 seconds, and more preferably, from about 2 seconds to about 8 seconds. Thereafter, the plasma power may be turned off. In one example, ammonia, nitrogen, hydrogen, or combinations thereof may be used as the reagent to form an ammonia plasma, a nitrogen plasma, a hydrogen plasma, or a combined plasma. The reactant plasma reacts with the adsorbed ruthenium precursor on the substrate to form a ruthenium material thereon. In one example, the reactant plasma is used as a reductant to form metallic ruthenium. However, a variety of reactants may be used to form ruthenium materials having a wide range of compositions. In another example, a boron-containing reactant compound (e.g., diborane) is used to form a ruthenium material containing boride. In another example, a silicon-containing reactant compound (e.g., silane) is used to form a ruthenium material containing silicide.

The process chamber or substrate may be exposed to a second purge step to remove excess precursors or contaminants from the previous step. The flow rate of the reagent gas may be maintained or adjusted from the previous step during the purge step. An optional purge gas may be administered into the process chamber having a flow rate within a range from about 100 sccm to about 2,000 sccm, preferably, from about 200 sccm to about 1,000 sccm, and more preferably, from about 300 sccm to about 700 sccm, for example, about 500 sccm. The second purge step may be conducted for a time period within a range from about 0.1 seconds to about 8 seconds preferably, from about 1 second to about 5 seconds, and more preferably, from about 2 seconds to about 4 seconds.

The ALD cycle may be repeated until a predetermined thickness of the ruthenium material is deposited on the substrate. The ruthenium material may be deposited having a thickness of less than 1,000 Å, preferably, less than 500 Å, and more preferably, within a range from about 10 Å to about 100 Å, for example, about 30 Å. The processes as described herein may be used to deposit a ruthenium material at a rate of at least about 0.15 Å/cycle, preferably, at least about 0.25 Å/cycle, more preferably, at least about 0.35 Å/cycle, or faster. In another embodiment, the processes as described herein overcome shortcomings of the prior art related to nucleation delay. There is no detectable nucleation delay during many, if not most, of the experiments described herein for depositing the ruthenium materials.

In another embodiment, a ruthenium material may be formed during another PE-ALD process that provides sequentially exposing the substrate to pulses of a ruthenium precursor and an active reagent, such as a reagent plasma. The substrate may be exposed to a ruthenium precursor gas formed by passing a carrier gas through an ampoule containing a ruthenium precursor, as described herein. The ruthenium precursor gas usually has a flow rate within a range from about 100 sccm to about 2,000 sccm, preferably, from about 200 sccm to about 1,000 sccm, and more preferably, from about 300 sccm to about 700 sccm, for example, about 500 sccm. The substrate may be exposed to the deposition gas containing the ruthenium precursor and the reagent gas for a time period within a range from about 0.1 seconds to about 8 seconds, preferably, from about 1 second to about 5 seconds, and more preferably from about 2 seconds to about 4 seconds. The flow of the ruthenium precursor gas may be stopped once the ruthenium precursor is adsorbed on the substrate. The ruthenium precursor may be a discontinuous layer, a continuous layer, or even multiple layers.

Subsequently, the substrate and chamber may be exposed to a purge step. A purge gas may be administered into the process chamber during the purge step. In one aspect, the purge gas is the reagent gas, such as ammonia, nitrogen, or hydrogen. In another aspect, the purge gas may be different than the reagent gas. For example, the reagent gas may be ammonia and the purge gas may be nitrogen, hydrogen, or argon. The purge gas may have a flow rate within a range from about 100 sccm to about 2,000 sccm, preferably, from about 200 sccm to about 1,000 sccm, and more preferably, from about 300 sccm to about 700 sccm, for example, about 500 sccm. During this purge step, excess ruthenium precursor and other contaminants are removed from the process chamber. The purge step may be conducted for a time period within a range from about 0.1 seconds to about 8 seconds, preferably, from about 1 second to about 5 seconds, and more preferably, from about 2 seconds to about 4 seconds. A carrier gas, a purge gas and a process gas may contain nitrogen, hydrogen, argon, neon, helium, or combinations thereof.

The substrate and the adsorbed ruthenium precursor thereon may be exposed to the reagent gas during the next step of the ALD process. Optionally, a carrier gas may be administered at the same time as the reagent gas into the process chamber. The reagent gas may be ignited to form a plasma. The reagent gas usually has a flow rate within a range from about 100 sccm to about 3,000 sccm, preferably, from about 200 sccm to about 2,000 sccm, and more preferably, from about 500 sccm to about 1,500 sccm. In one example, ammonia is used as a reagent gas with a flow rate of about 1,500 sccm. The substrate may be exposed to the plasma for a time period within a range from about 0.1 seconds to about 20 seconds, preferably, from about 1 second to about 10 seconds, and more preferably, from about 2 seconds to about 8 seconds. Thereafter, the plasma power may be turned off. In one example, the reagent may be ammonia, nitrogen, hydrogen, or combinations thereof, while the plasma may be an ammonia plasma, a nitrogen plasma, a hydrogen plasma, or a combination thereof. The reactant plasma reacts with the adsorbed ruthenium precursor on the substrate to form a ruthenium material thereon. Preferably, the reactant plasma is used as a reductant to form metallic ruthenium. However, a variety of reactants may be used to form ruthenium materials having a wide range of compositions, as described herein.

The process chamber or substrate may be exposed to a second purge step to remove excess precursors or contaminants therefrom. The flow of the reagent gas may be stopped at the end of the previous step and started during the purge step if the reagent gas is used as a purge gas. Alternatively, a purge gas that is different than the reagent gas may be administered into the process chamber. The reagent gas or purge gas may have a flow rate within a range from about 100 sccm to about 2,000 sccm, preferably, from about 200 sccm to about 1,000 sccm, and more preferably, from about 300 sccm to about 700 sccm, for example, about 500 sccm. The second purge step may be conducted for a time period within a range from about 0.1 seconds to about 8 seconds, preferably, from about 1 second to about 5 seconds, and more preferably, from about 2 seconds to about 4 seconds.

The ALD cycle may be repeated until a predetermined thickness of the ruthenium material is deposited on the substrate. The ruthenium material may be deposited having a thickness less than 1,000 Å, preferably, less than 500 Å, and more preferably, within a range from about 10 Å to about 100 Å, for example, about 30 Å. The processes as described herein may be used to deposit a ruthenium material at a rate of at least about 0.15 Å/cycle, preferably, at least about 0.25 Å/cycle, more preferably, at least about 0.35 Å/cycle, or faster. In another embodiment, the processes as described herein overcome shortcomings of the prior art related to nucleation delay. There is no detectable nucleation delay during many, if not most, of the experiments described herein for depositing the ruthenium materials.

Generally, in order to use a ruthenocene compound during an ALD process, a surface treatment step may be needed unless the surface is terminated with a hydroxyl group, such as —OH, or an electron-rich surface, such as a metallic layer. On a barrier layer such as tantalum nitride, ruthenocene precursors usually do not form ruthenium materials by ALD processes without a pre-treatment step. Even with a pre-treatment step, such as the hydroxylation of the barrier surface, the randomly placed nucleation sites cause ruthenocene to form satellites or islands of ruthenium during the deposition process. Therefore, an ALD process using a ruthenocene precursor generally deposits a ruthenium material having an increased electrical resistance probably due to the unevenness of the ruthenium material. Also, the deposition process may suffer a nucleation delay due to the ruthenocene precursor. Furthermore, high adsorption temperatures of above 400° C. are usually required to form ruthenium layers from ruthenocene precursors. Such high temperatures may damage device structure within a sensitive low-k dielectric environment, for example, within a copper back end of line (BEOL) process. Hence, it is preferred to perform ALD processes at temperatures of less than about 400° C., preferably, less than about 350° C. Further, ruthenium materials deposited from ruthenocene precursors used during an ALD process on dielectric surfaces tend to fail tape testing due to the low adhesion of the underlying layer. Therefore, in many embodiments, ruthenocene compounds, such as bis(ethylcyclopentadienyl) ruthenium, bis(cyclopentadienyl) ruthenium, and bis(pentamethylcyclopentadienyl) ruthenium are less desirable ruthenium precursors than precursors containing pyrrolyl ligands.

Embodiments of the invention include improved methodologies overcoming disadvantages of the prior art, and preferred precursors and chemistries providing additional advantages over the prior art. A family of ruthenium precursors useful to form a ruthenium material during the deposition process described herein includes pyrrolyl ruthenium precursors. The pyrrolyl ligand provides the pyrrolyl ruthenium precursor advantages over previous ruthenium precursors (e.g., ruthenocene and derivatives thereof) during an ALD process. The pyrrolyl ligand is more thermodynamically stable than many ligands, as well as forms a very volatile chemical precursor. A pyrrolyl ruthenium precursor contains ruthenium and at least one pyrrolyl ligand or at least one pyrrolyl derivative ligand. A pyrrolyl ruthenium precursor may have a pyrrolyl ligand, such as, for example, 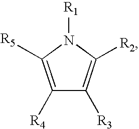
where R₁, R₂, R₃, R₄, and R₅ are each independently absent, hydrogen, an alkyl group (e.g., methyl, ethyl, propyl, butyl, amyl, or higher), an amine group, an alkoxy group, an alcohol group, an aryl group, another pyrrolyl group (e.g., 2,2′-bipyrrolyl), a pyrazole group, derivatives thereof, or combinations thereof. The pyrrolyl ligand may have any two or more of R₁, R₂, R₃, R₄, and R₅ connected together by a chemical group. For example, R₂ and R₃ may be a portion of a ring structure such as an indolyl group or derivative thereof. A pyrrolyl ruthenium precursor as used herein refers to any chemical compound containing ruthenium and at least one pyrrolyl ligand or at least one derivative of a pyrrolyl ligand. In preferred examples, a pyrrolyl ruthenium precursor may include bis(tetramethylpyrrolyl) ruthenium, bis(2,5-dimethylpyrrolyl) ruthenium bis(2,5-diethylpyrrolyl) ruthenium, bis(tetraethylpyrrolyl) ruthenium, pentadienyl tetramethylpyrrolyl ruthenium, pentadienyl 2,5-dimethylpyrrolyl ruthenium, pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium, or derivatives thereof.

An important precursor characteristic is to have a favorable vapor pressure for ALD processes. Deposition precursors may have gas, liquid, or solid states at ambient temperature and pressure. However, within the ALD chamber, precursors are usually volatilized as gas or plasma. Precursors are usually heated prior to delivery into the process chamber. Although many variables affect the deposition rate during an ALD process to form ruthenium material, the size of the ligand on a pyrrolyl ruthenium precursor is an important consideration in order to achieve a predetermined deposition rate. The size of the ligand contributes to determining the specific temperature and pressure required to vaporize the pyrrolyl ruthenium precursor. Furthermore, a pyrrolyl ruthenium precursor has a particular ligand steric hindrance proportional to the size of the ligands. In general, larger ligands provide more steric hindrance. Therefore, less molecules of a precursor containing more bulky ligands may be adsorbed on a surface during an an ALD half reaction while exposing the substrate to the precursor than if the precursor contained less bulky ligands. The steric hindrance effect limits the amount of adsorbed precursors on the surface. Therefore, by decreasing the steric hindrance of the ligand, a more concentrated monolayer of a pyrrolyl ruthenium precursor may be formed on the surface. The overall deposition rate is proportionally related to the amount of adsorbed precursor on the surface, since an increased deposition rate is usually achieved by having more of the precursor adsorbed to the surface. Ligands that contain smaller functional groups (e.g., hydrogen or methyl) generally provide less steric hindrance than ligands that contain larger functional groups (e.g., aryl). Also, the position on the ligand motif may affect the steric hindrance of the precursor. Generally, the inner positions, R₂ and R₅, have less of an effect than do the outer positions, R₃ and R₄. For example, a pyrrolyl ruthenium precursor containing R₂ and R₅ equal to hydrogen groups and R₃ and R₄ equal to methyl groups has more steric hindrance than a pyrrolyl ruthenium precursor containing R₂ and R₅ equal to methyl groups and R₃ and R₄ equal to hydrogen groups.

A pyrrolyl ligand, as used herein, may be abbreviated by “py” and a pyrrolyl derivative ligand may be abbreviated by “R-py.” Exemplary pyrrolyl ruthenium precursors useful to form a ruthenium material during the deposition process described herein include alkyl pyrrolyl ruthenium precursors (e.g., (Rₓ-py)Ru), bis(pyrrolyl) ruthenium precursors (e.g., (py)₂Ru) and dienyl pyrrolyl ruthenium precursors (e.g., (Cp)(py)Ru). Examples of alkyl pyrrolyl ruthenium precursors include methylpyrrolyl ruthenium, ethylpyrrolyl ruthenium, propylpyrrolyl ruthenium, dimethylpyrrolyl ruthenium diethylpyrrolyl ruthenium, dipropylpyrrolyl ruthenium, trimethylpyrrolyl ruthenium, triethylpyrrolyl ruthenium, tetramethylpyrrolyl ruthenium, tetraethylpyrrolyl ruthenium, or derivatives thereof. Examples of bis(pyrrolyl) ruthenium precursors include bis(pyrrolyl) ruthenium, bis(methylpyrrolyl) ruthenium, bis(ethylpyrrolyl) ruthenium, bis(propylpyrrolyl) ruthenium, bis(dimethylpyrrolyl) ruthenium, bis(diethylpyrrolyl) ruthenium, bis(dipropylpyrrolyl) ruthenium, bis(trimethylpyrrolyl) ruthenium, bis(triethylpyrrolyl) ruthenium, bis(tetramethylpyrrolyl) ruthenium, bis(tetraethylpyrrolyl) ruthenium, methylpyrrolyl pyrrolyl ruthenium, ethylpyrrolyl pyrrolyl ruthenium, propylpyrrolyl pyrrolyl ruthenium, dimethylpyrrolyl pyrrolyl ruthenium, diethylpyrrolyl pyrrolyl ruthenium, dipropylpyrrolyl pyrrolyl ruthenium, trimethylpyrrolyl pyrrolyl ruthenium, triethylpyrrolyl pyrrolyl ruthenium, tetramethylpyrrolyl pyrrolyl ruthenium tetraethylpyrrolyl pyrrolyl ruthenium, or derivatives thereof.

A dienyl pyrrolyl ruthenium precursor contains at least one dienyl ligand and at least one pyrrolyl ligand. The dienyl ligand may contain a carbon backbone with as little as four carbon atoms or as many as about ten carbon atoms, preferably, about five or six. The dienyl ligand may have a ring structure (e.g., cyclopentadienyl) or may be an open alkyl chain (e.g., pentadienyl). Also, dienyl ligand may contain no alkyl groups, one alkyl group, or many alkyl groups.

In one embodiment, the dienyl pyrrolyl ruthenium precursor contains a pentadienyl ligand or an alkylpentadienyl ligand. Examples of pentadienyl pyrrolyl ruthenium precursors include pentadienyl pyrrolyl ruthenium, pentadienyl methylpyrrolyl ruthenium, pentadienyl ethylpyrrolyl ruthenium, pentadienyl propylpyrrolyl ruthenium pentadienyl dimethylpyrrolyl ruthenium, pentadienyl diethylpyrrolyl ruthenium pentadienyl dipropylpyrrolyl ruthenium, pentadienyl trimethylpyrrolyl ruthenium pentadienyl triethylpyrrolyl ruthenium, pentadienyl tetramethylpyrrolyl ruthenium, pentadienyl tetraethylpyrrolyl ruthenium, or derivatives thereof. Examples of alkylpentadienyl pyrrolyl ruthenium precursors include alkylpentadienyl pyrrolyl ruthenium, alkylpentadienyl methylpyrrolyl ruthenium, alkylpentadienyl ethylpyrrolyl ruthenium, alkylpentadienyl propylpyrrolyl ruthenium, alkylpentadienyl dimethylpyrrolyl ruthenium, alkylpentadienyl diethylpyrrolyl ruthenium, alkylpentadienyl dipropylpyrrolyl ruthenium, alkylpentadienyl trimethylpyrrolyl ruthenium, alkylpentadienyl triethylpyrrolyl ruthenium, alkylpentadienyl tetramethylpyrrolyl ruthenium, alkylpentadienyl tetraethylpyrrolyl ruthenium, or derivatives thereof.

In another embodiment, the dienyl pyrrolyl ruthenium precursor contains a cyclopentadienyl ligand or an alkylcyclopentadienyl ligand. Examples of cyclopentadienyl pyrrolyl ruthenium precursors include cyclopentadienyl pyrrolyl ruthenium, cyclopentadienyl methylpyrrolyl ruthenium, cyclopentadienyl ethylpyrrolyl ruthenium, cyclopentadienyl propylpyrrolyl ruthenium, cyclopentadienyl dimethylpyrrolyl ruthenium, cyclopentadienyl diethylpyrrolyl ruthenium, cyclopentadienyl dipropylpyrrolyl ruthenium, cyclopentadienyl trimethylpyrrolyl ruthenium, cyclopentadienyl triethylpyrrolyl ruthenium, cyclopentadienyl tetramethylpyrrolyl ruthenium, cyclopentadienyl tetraethylpyrrolyl ruthenium, or derivatives thereof. Examples of alkylcyclopentadienyl pyrrolyl ruthenium precursors include alkylcyclopentadienyl pyrrolyl ruthenium, alkylcyclopentadienyl methylpyrrolyl ruthenium, alkylcyclopentadienyl ethylpyrrolyl ruthenium, alkylcyclopentadienyl propylpyrrolyl ruthenium, alkylcyclopentadienyl dimethylpyrrolyl ruthenium, alkylcyclopentadienyl diethylpyrrolyl ruthenium, alkylcyclopentadienyl dipropylpyrrolyl ruthenium, alkylcyclopentadienyl trimethylpyrrolyl ruthenium, alkylcyclopentadienyl triethylpyrrolyl ruthenium, alkylcyclopentadienyl tetramethylpyrrolyl ruthenium, alkylcyclopentadienyl tetraethylpyrrolyl ruthenium, or derivatives thereof.

In another embodiment, a ruthenium precursor may contain no pyrrolyl ligand or pyrrolyl derivative ligand, but instead, contains at least one open chain dienyl ligand, such as CH₂CRCHCRCH₂, where R is independently an alkyl group or hydrogen. A ruthenium precursor may have two open-chain dienyl ligands, such as pentadienyl or heptadienyl. A bis(pentadienyl) ruthenium compound has a generic chemical formula (CH₂CRCHCRCH₂)₂Ru, where R is independently an alkyl group or hydrogen. Usually, R is independently hydrogen, methyl, ethyl, propyl or butyl. Therefore, ruthenium precursors may include bis(dialkylpentadienyl) ruthenium compounds, bis(alkylpentadienyl) ruthenium compounds, bis(pentadienyl) ruthenium compounds, or combinations thereof. Examples of ruthenium precursors include bis(2,4-dimethylpentadienyl) ruthenium, bis(2,4-diethyl pentadienyl) ruthenium, bis(2,4-diisopropyl pentadienyl) ruthenium, bis(2,4-ditertbutylpentadienyl) ruthenium bis(methylpentadienyl) ruthenium, bis(ethyl pentadienyl) ruthenium, bis(isopropylpentadienyl) ruthenium, bis(tertbutylpentadienyl) ruthenium, derivatives thereof, or combinations thereof. In some embodiments, other ruthenium precursors include tris(2,2,6,6-tetramethyl-3,5-heptanedionato) ruthenium, dicarbonyl pentadienyl ruthenium, ruthenium acetyl acetonate, 2,4-dimethylpentadienyl cyclopentadienyl ruthenium, bis(2,2,6,6-tetramethyl-3,5-heptanedionato) (1,5-cyclooctadiene) ruthenium, 2,4-dimethylpentadienyl methylcyclopentadienyl ruthenium, 1,5-cyclooctadiene cyclopentadienyl ruthenium, 1,5-cyclooctadiene methylcyclopentadienyl ruthenium, 1,5-cyclooctadiene ethylcyclopentadienyl ruthenium, 2,4-dimethylpentadienyl ethylcyclopentadienyl ruthenium, 2,4-dimethylpentadienyl isopropylcyclopentadienyl ruthenium, bis(N,N-dimethyl 1,3-tetramethyl diiminato) 1,5-cyclooctadiene ruthenium, bis(N,N-dimethyl 1,3-dimethyl diiminato) 1,5-cyclooctadiene ruthenium, bis(allyl) 1,5-cyclooctadiene ruthenium, η⁶-C₆H₆ 1,3-cyclohexadiene ruthenium, bis(1,1-dimethyl-2-aminoethoxylato) 1,5-cyclooctadiene ruthenium, bis(1,1-dimethyl-2-aminoethylaminato) 1,5-cyclooctadiene ruthenium, derivatives thereof, or combinations thereof.

The various ruthenium precursors containing a pyrrolyl ligand, an open chain dienyl ligand or a combination thereof may be used with at least one reagent to form a ruthenium material. The ruthenium precursor and the reagent may be sequentially introduced into the process chamber during a thermal ALD process or a PE-ALD process. A suitable reagent for forming a ruthenium material may be a reducing gas and includes hydrogen (e.g., H₂ or atomic-H), atomic-N, ammonia (NH₃), hydrazine (N₂H₄), silane (SiH₄), disilane (Si₂H₆), trisilane (Si₃H₈), tetrasilane (Si₄H₁₀), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triborane, tetraborane, pentaborane, trimethylborane (Me₃B), triethylborane (Et₃B), derivatives thereof, plasmas thereof, or combinations thereof.

In an alternative embodiment, the reagent gas may include oxygen-containing gases, such as oxygen (e.g., O₂), nitrous oxide (N₂O), nitric oxide (NO), nitrogen dioxide (NO₂), derivatives thereof, or combinations thereof. Furthermore traditional reducing agents may be combined with the oxygen-containing reagents to form a reagent gas. Oxygen-containing gases that may be used during deposition processes to form ruthenium materials have traditionally been used in the chemical art as an oxidant. However, ligands on a metal-organic compound containing a noble metal (e.g., Ru) are usually more susceptible to the oxygen-containing reductants than the noble metal. Therefore, the ligand is often oxidized from the metal center while the metal ion is reduced by the ligand to form the elemental metal. In one embodiment, the reagent gas contains ambient oxygen from the air that is dried over sieves to reduce ambient water. Additional disclosure that may be used during processes described herein, including a process for depositing a ruthenium material by using an oxygen-containing gas, is further described in commonly assigned and co-pending U.S. Ser. No. 10/811,230, entitled “Ruthenium Layer Formation for Copper Film Deposition,” filed Mar. 26, 2004, and published as U.S. Pub. No. 2004-0241321, which is incorporated herein by reference in its entirety.

The time interval for the pulse of the ruthenium precursor is variable depending upon a number of factors such as, for example, the volume capacity of the process chamber employed, the vacuum system coupled thereto and the volatility/reactivity of the reactants used during the ALD process. For example, (1) a large-volume process chamber may lead to a longer time to stabilize the process conditions, such as, for example, carrier/purge gas flow and temperature, which then requires a longer pulse time; (2) a lower flow rate for the process gas may also lead to a longer time to stabilize the process conditions, which in turn requires a longer pulse time; and (3) a lower chamber pressure means that the process gas is evacuated from the process chamber more quickly, usually needing a longer pulse time. In general, the process conditions are advantageously selected so that a pulse of the ruthenium precursor provides a sufficient amount of precursor so that at least a monolayer of the ruthenium precursor is adsorbed on the substrate. Thereafter, excess ruthenium precursor remaining in the chamber may be removed from the process chamber by the constant carrier gas stream in combination with the vacuum system.

In one embodiment, the time interval for each of the pulses of the ruthenium precursor and the reagent gas may have the same duration. The duration of the pulse of the ruthenium precursor may be identical to the duration of the pulse of the reagent gas. For such an embodiment, a time interval (T₁) for the pulse of the ruthenium precursor is equal to a time interval (T₂) for the pulse of the reagent gas.

Alternatively, the time interval for each of the pulses of the ruthenium precursor and the reagent gas may have different durations. The duration of the pulse of the ruthenium precursor may be shorter or longer than the duration of the pulse of the reagent gas. For such an embodiment, a time interval (T₁) for the pulse of the ruthenium precursor is different than the time interval (T₂) for the pulse of the reagent gas.

In addition, the periods of non-pulsing between each of the pulses of the ruthenium precursor and the reagent gas may have the same duration. The duration of the period of non-pulsing between each pulse of the ruthenium precursor and each pulse of the reagent gas is identical. For such an embodiment, a time interval (T₃) of non-pulsing between the pulse of the ruthenium precursor and the pulse of the reagent gas is equal to a time interval (T₄) of non-pulsing between the pulse of the reagent gas and the pulse of the ruthenium precursor. During the time periods of non-pulsing, only the constant carrier gas stream is provided to the process chamber.

Alternatively, the periods of non-pulsing between each of the pulses of the ruthenium precursor and the reagent gas may have a different duration. The duration of the period of non-pulsing between each pulse of the ruthenium precursor and each pulse of the reagent gas may be shorter or longer than the duration of the period of non-pulsing between each pulse of the reagent gas and the ruthenium precursor. For such an embodiment, a time interval (T₃) of non-pulsing between the pulse of the ruthenium precursor and the pulse of the reagent gas is different from a time interval (T₄) of non-pulsing between the pulse of the reagent gas and the pulse of ruthenium precursor. During the time periods of non-pulsing only the constant carrier gas stream is provided to the process chamber.

Additionally, the time intervals for each pulse of the ruthenium precursor, the reagent gas and the periods of non-pulsing therebetween for each deposition cycle may have the same duration. For such an embodiment, a time interval (T₁) for the ruthenium precursor, a time interval (T₂) for the reagent gas, a time interval (T₃) of non-pulsing between the pulse of the ruthenium precursor and the pulse of the reagent gas and a time interval (T₄) of non-pulsing between the pulse of the reagent gas and the pulse of the ruthenium precursor each have the same value for each deposition cycle. For example, in a first deposition cycle (C₁), a time interval (T₁) for the pulse of the ruthenium precursor has the same duration as the time interval (T₁) for the pulse of the ruthenium precursor in subsequent deposition cycles (C₂ . . . Cₙ). Similarly, the duration of each pulse of the reagent gas and the periods of non-pulsing between the pulse of the ruthenium precursor and the reagent gas in the first deposition cycle (C₁) is the same as the duration of each pulse of the reagent gas and the periods of non-pulsing between the pulse of the ruthenium precursor and the reagent gas in subsequent deposition cycles (C₂ . . . Cₙ), respectively.

Alternatively, the time intervals for at least one pulse of the ruthenium precursor, the reagent gas and the periods of non-pulsing therebetween for one or more of the deposition cycles of the ruthenium material deposition process may have different durations. For such an embodiment, one or more of the time intervals (T₁) for the pulses of the ruthenium precursor, the time intervals (T₂) for the pulses of the reagent gas, the time intervals (T₃) of non-pulsing between the pulse of the ruthenium precursor and the reagent gas and the time intervals (T₄) of non-pulsing between the pulses of the reagent gas and the ruthenium precursor may have different values for one or more deposition cycles of the cyclical deposition process. For example, in a first deposition cycle (C₁), the time interval (T₁) for the pulse of the ruthenium precursor may be longer or shorter than one or more time interval (T₁) for the pulse of the ruthenium precursor in subsequent deposition cycles (C₂ . . . Cₙ). Similarly, the durations of the pulses of the reagent gas and the periods of non-pulsing between the pulse of the ruthenium precursor and the reagent gas in the first deposition cycle (C₁) may be the same or different than the duration of each pulse of the reagent gas and the periods of non-pulsing between the pulse of the ruthenium precursor and the reagent gas in subsequent deposition cycles (C₂ . . . Cₙ).

In some embodiments, a constant flow of a carrier gas or a purge gas may be provided to the process chamber modulated by alternating periods of pulsing and non-pulsing where the periods of pulsing alternate between the ruthenium precursor and the reagent gas along with the carrier/purge gas stream, while the periods of non-pulsing include only the carrier/purge gas stream.

Formation of Copper Interconnects

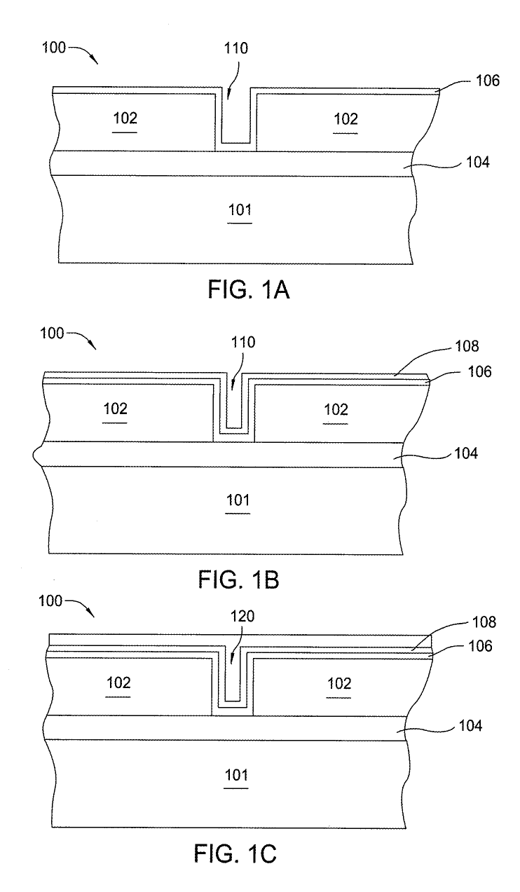

FIGS. 1A-1C illustrate cross-sectional views of substrate 100 at different stages of an interconnect fabrication sequence incorporating the ruthenium material formed by ALD processes as described herein. FIG. 1A illustrates a cross-sectional view of substrate 100 having metal contact 104 and dielectric layer 102 formed disposed on layer 101. Layer 101 may contain a semiconductor material, such as, silicon, germanium, or gallium arsenide. Dielectric layer 102 may contain an insulating material, such as, silicon dioxide, silicon nitride, silicon oxynitride, and/or carbon-doped silicon oxides, such as, SiOₓC_{y}, for example, BLACK DIAMOND® low-k dielectric, available from Applied Materials, Inc., located in Santa Clara, Calif. Metal contact 104 may contain copper, aluminum, tungsten, or alloys thereof. Aperture 110 may be defined in dielectric layer 102 to provide openings over metal contact 104. Aperture 110 may be formed in dielectric layer 102 using conventional lithography and etching techniques.

Barrier layer 106 may be formed in aperture 110 and over dielectric layer 102 and a portion of metal contact 104. Barrier layer 106 may include one or more refractory metal-containing layers used as a copper-barrier material such as, for example, titanium, titanium nitride, titanium silicon nitride tantalum, tantalum nitride tantalum silicon nitride, tungsten, tungsten nitride, derivatives thereof, or combinations thereof. Barrier layer 106 may be formed using a suitable deposition process, such as ALD, chemical vapor deposition (CVD), or physical vapor deposition (PVD). For example, titanium nitride may be formed from titanium tetrachloride and ammonia during a CVD process or an ALD process. In one embodiment, tantalum and/or tantalum nitride is deposited as a barrier layer by an ALD process as described in commonly assigned U.S. Pub. No. 2002-0106846, and issued as U.S. Pat. No. 6,951,804, which is incorporated herein by reference in its entirety.

Ruthenium material 108 is formed on barrier layer 106 by an ALD process as described herein (FIG. 1B). The thickness for ruthenium material 108 is variable depending on the fabricated device structure and geometry. Typically, the thickness for ruthenium material 108 is less than about 1,000 Å, preferably, within a range from about 10 Å to about 500 Å. In one embodiment, ruthenium material 108 has a thickness of less than about 100 Å, for example, about 50 Å.

Thereafter, aperture 110 may be filled with metal layer 120 to complete the interconnect (FIG. 1C). Metal layer 120 may contain copper, tungsten, aluminum or an alloy thereof and may be formed using one or more suitable deposition processes. In one embodiment, for example, metal layer 120 may contain a seed layer and a bulk layer formed on ruthenium material 108 by using one or more deposition processes that include a CVD process, an ALD process, a PVD process, an electroless deposition process, an electrochemical plating (ECP) process, or combinations thereof. Substrate 100 may be exposed to a pretreatment process, such as a soaking process, prior to depositing ruthenium material 108, as well as prior to depositing metal layer 120, including a pre-nucleation soak process to ruthenium material 108 and a post-nucleation soak process to a seed layer. Additional disclosure of processes for depositing a tungsten material on a ruthenium material is further described in commonly assigned and co-pending U.S. Ser. No. 11/009,331, entitled “Ruthenium as an Underlayer for Tungsten Film Deposition,” filed Dec. 10, 2004, and published as U.S. Pub. No. U.S. Pub. No. 2006-0128150, which is incorporated herein by reference in its entirety.

In one embodiment, metal layer 120 preferably contains copper or a copper alloy. For example, a copper seed layer may be formed on the ruthenium material by a CVD process, and thereafter, bulk copper may be deposited to fill the interconnect by an ECP process. In another example, a copper seed layer may be formed on the ruthenium material by a PVD process, and thereafter, bulk copper may be deposited to fill the interconnect by an ECP process. In another example, a copper seed layer may be formed on the ruthenium material by an electroless process, and thereafter, bulk copper may be deposited to fill the interconnect by an ECP process. In another example, the ruthenium material may serve as a seed layer to which a copper bulk fill may be directly deposited by an ECP process or an electroless deposition process.

In another embodiment, metal layer 120 may contain tungsten or a tungsten alloy. For example, a tungsten seed layer may be formed on the ruthenium material by an ALD process, and thereafter, bulk tungsten may be deposited to fill the interconnect by a CVD process or a pulsed-CVD process. In another example, a tungsten seed layer may be formed on the ruthenium material by a PVD process, and thereafter, bulk tungsten may be deposited to fill the interconnect by a CVD process or a pulsed-CVD process. In another example, a tungsten seed layer may be formed on the ruthenium material by an ALD process, and thereafter, bulk tungsten may be deposited to fill the interconnect by an ECP process. In another example, the ruthenium material may serve as a seed layer to which a tungsten bulk fill may be directly deposited by a CVD process or a pulsed-CVD process.

Several integration sequences may be conducted in order to form ruthenium material 108 within aperture 110. In one example, the subsequent steps follow: a) pre-clean of the substrate; b) deposition of a barrier layer (e.g., ALD of TaN); c) deposition of ruthenium by ALD; and d) deposition of seed copper by electroless, ECP, or PVD followed by deposition of bulk copper by ECP. In another example, the subsequent steps follow: a) deposition of a barrier layer (e.g., ALD of TaN); b) punch through step; c) deposition of ruthenium by ALD; and d) deposition of seed copper by electroless, ECP, or PVD followed by deposition of bulk copper by ECP. In another example, the subsequent steps follow: a) deposition of ruthenium by ALD; b) punch through step; c) deposition of ruthenium by ALD; and d) deposition of seed copper by electroless, ECP, or PVD followed by deposition of bulk copper by electroless, ECP, or PVD. In another example, the subsequent steps follow: a) deposition of ruthenium by ALD; b) punch through step; c) deposition of ruthenium by ALD; and d) deposition of copper by electroless or ECP. In another embodiment, the subsequent steps follow: a) pre-clean of the substrate; b) deposition of ruthenium by ALD; and c) deposition of seed copper by electroless, ECP, or PVD, followed by deposition of bulk copper by ECP. In another example, the subsequent steps follow: a) deposition of a barrier layer (e.g., ALD of TaN); b) deposition of ruthenium by ALD; c) punch through step; d) deposition of ruthenium by ALD; and e) deposition of seed copper by electroless, ECP, or PVD, followed by deposition of bulk copper by ECP. In another example, the subsequent steps follow: a) deposition of a barrier layer (e.g., ALD of TaN); b) punch through step; c) deposition of a barrier layer (e.g., ALD of TaN); d) deposition of ruthenium by ALD; e) deposition of seed copper by electroless, ECP, or PVD; and f) deposition of bulk copper by ECP. In one example, the subsequent steps follow: a) pre-clean of the substrate; b) deposition of a barrier layer (e.g., ALD of TaN); c) deposition of ruthenium by ALD; and d) deposition of copper bulk by electroless or ECP.

The pre-clean steps include methods to clean or purify the via, such as the removal of residue at the bottom of the via (e.g., carbon) or reduction of copper oxide to copper metal. Punch through steps include a method to remove material (e.g., barrier layer) from the bottom of the via to expose conductive layer, such as copper. Further disclosure of punch through steps is described in more detail in the commonly assigned, U.S. Pat. No. 6,498,091, which is incorporated herein by reference in its entirety. The punch through steps may be conducted within a process chamber, such as either a barrier chamber or a clean chamber. In embodiments of the invention, clean steps and punch through steps are applied to ruthenium barrier layers. Further disclosure of overall integrated methods are described in more detail in the commonly assigned, U.S. Pat. No. 7,049,226, which is incorporated herein by reference in its entirety.

Ruthenium Deposition on Dielectric Materials

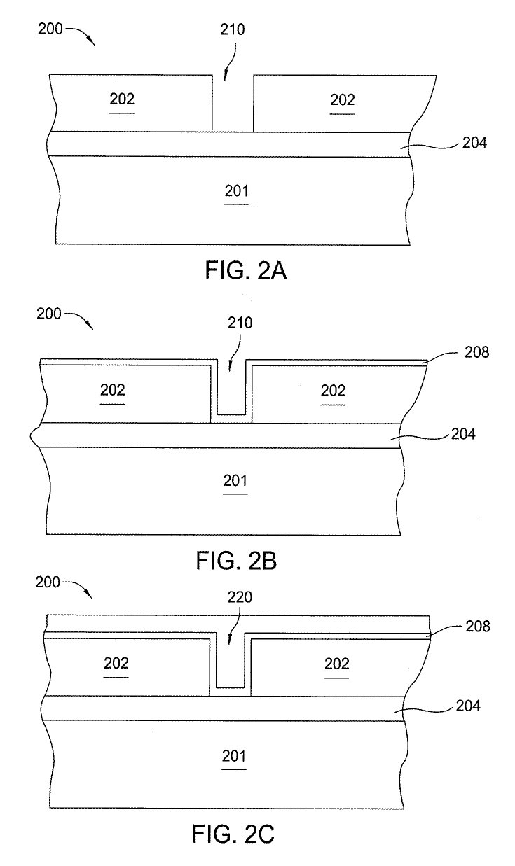

In another embodiment, FIGS. 2A-2C illustrate cross-sectional views of substrate 200 at different stages of an interconnect fabrication sequence incorporating the ruthenium material formed by ALD processes as described herein. Ruthenium material 208 may be deposited directly on dielectric material 202 (e.g., low-k) disposed on substrate 200 by an ALD process. Ruthenium material 208 may be used as a barrier layer, as well as a seed layer for subsequent deposition of metal layer 220. Temperatures of above 400° C. may damage device structures, such as within a sensitive, low-k dielectric environment, for example, within a BEOL process. Therefore it is preferred to perform degassing processes as well as ALD processes at temperatures less than 400° C.

FIG. 2A illustrates a cross-sectional view of substrate 200 having metal contact 204 and dielectric layer 202 formed disposed on layer 201. Layer 201 may contain a semiconductor material such as, for example, silicon, germanium, or gallium arsenide. Dielectric layer 202 may contain an insulating material, such as, silicon dioxide, silicon nitride, silicon oxynitride, and/or carbon-doped silicon oxides, such as SiOₓC_{y}, for example, BLACK DIAMOND® low-k dielectric, available from Applied Materials, Inc., located in Santa Clara, Calif., or other dielectric materials, such as, SILK® or CORAL®. Also, low-k dielectric material may include aerogels, such as ELK® available from Schumacher, Inc. Other dielectric materials include: silicon oxides silicon nitride, silicon oxynitride, and high-k materials used in metal gate applications, such as, for example, aluminum oxide, hafnium oxide, hafnium silicate, tantalum oxide titanium oxide, boron strontium titanate, zirconium oxide, zirconium silicate, derivatives thereof, or combinations thereof. Aperture 210 may be defined in dielectric layer 202 using conventional lithography and etching techniques.

Substrate 200 containing dielectric layer 202 may initially be exposed to a degassing process for about 5 minutes or less, for example, about 1 minute, while heating substrate 200 to a temperature within a range from about 250° C. to about 400° C., for example, about 350° C. The degassing process may further include maintaining the substrate in a reduced vacuum at a pressure within the range from about 1×10⁻⁷ Torr to about 1×10⁻⁵ Torr, for example, about 5×10⁻⁶ Torr. The degassing process removes volatile surface contaminates, such as water vapor, solvents or volatile organic compounds.

Ruthenium material 208 may be formed using an ALD process as described herein (FIG. 2B). Generally, a single cycle of the ALD process includes sequentially exposing dielectric material 202 to a pyrrolyl ruthenium precursor and a reagent to form ruthenium material 208. The ALD cycle is repeated until ruthenium material 208 has a desired thickness. The thickness for ruthenium material 208 is variable depending on the device structure to be fabricated. Typically, the thickness for ruthenium material 208 is less than about 1,000 Å, preferably, within a range from about 10 Å to about 500 Å. In one embodiment, ruthenium material 208 has a thickness of less than about 100 Å, for example, about 50 Å.

The chamber or the substrate may be heated to a temperature of less than about 500° C., preferably, within a range from about 100° C. to about 450° C., and more preferably, from about 150° C. to about 400° C., for example, about 300° C. The relatively low deposition temperature is highly advantageous since as mentioned previously, the risk of device damage, particularly where low-k materials are employed, rises significantly as temperatures are above about 400° C. Yet, such higher temperatures are typically required with prior art precursors in order to obtain adsorption on substrates so as to perform deposition by an ALD process.

Thereafter, aperture 210 may be filled with metal layer 220 to complete the interconnect (FIG. 2C). Metal layer 220 may contain copper, tungsten, aluminum, or an alloy thereof and may be formed using one or more suitable deposition processes. In one embodiment, for example, metal layer 220 may contain a seed layer and a bulk layer formed on ruthenium material 208 by using one or more deposition process that include a CVD process, an ALD process, a PVD process, an electroless deposition process, an electrochemical plating (ECP) process, or combinations thereof. Substrate 200 may be exposed to a pretreatment process, such as a soaking process, prior to depositing ruthenium material 208, as well as prior to depositing metal layer 220, including a pre-nucleation soak process to ruthenium material 208 and a post-nucleation soak process to a seed layer. In one embodiment, metal layer 220 contains copper or a copper alloy formed by the exemplary deposition processes as described for metal layer 120. In one embodiment, metal layer 220 contains tungsten or a tungsten alloy formed by the exemplary deposition processes as described for metal layer 120.

The pyrrolyl ruthenium precursors and deposition chemistries utilized in the various embodiments provide further significant advantages. The layers formed by the present ruthenium methodologies and precursors, such as pyrrolyl ruthenium precursors, have high nucleation density and uniformity. This is believed to promote freedom from surface defects such as satellites or islands in the resulting ruthenium material, in contrast to layers deposited by prior art methods and where prior methods employed solely ruthenocene compounds.

The pyrrolyl ruthenium precursors used to form ruthenium materials provide little or no nucleation delay during the ALD process. The deposited ruthenium material usually has a low carbon concentration resulting in a high electrical conductance.

Also, the pyrrolyl ruthenium precursor and the reagents are utilized in various embodiments during the ALD processes to deposit a ruthenium material on a barrier layer, especially a tantalum nitride barrier layer. Unlike other ALD processes that use ruthenocene, the present ruthenium methodologies and precursors are not limited with the need to pre-treat the barrier layer prior to the deposition of a ruthenium material. Excess process steps, such as pretreatment steps, are avoided by applying a pyrrolyl ruthenium precursor during an ALD process to increase the overall throughput of the production line.

Further, ruthenium materials deposited with the present methodologies, especially when employing a pyrrolyl ruthenium precursor, have superior adhesion properties to barrier layers as well as dielectric materials. It is believed the superior adhesion, at least in part, is due to the higher degree of uniformity and nucleation density, whereby a more level surface and fewer surface defects result. Furthermore ruthenocene compounds generally require a temperature above 400° C. in order to become adsorbed to a substrate surface during an ALD process. However, since the threshold of many low-k devices is around 400° C., ruthenocene compounds are not desirable ruthenium precursors for ALD processes.

The ruthenium materials formed from a pyrrolyl ruthenium precursor during the ALD processes as described herein generally have a sheet resistance of less than about 2,000 Ω/sq, preferably, less than about 1,000 Ω/sq, and more preferably, less than about 500 Ω/sq. For example, a ruthenium material may have a sheet resistance within a range from about 10 Ω/sq to about 250 Ω/sq.

A “substrate surface,” as used herein, refers to any substrate or material surface formed on a substrate upon which film processing is performed during a fabrication process. For example, a substrate surface on which processing can be performed includes materials such as, for example, silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum, or tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein deposit ruthenium materials on many substrates and surfaces. Substrates on which embodiments of the invention may be useful include but are not limited to semiconductor wafers, such as, for example, crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

“Atomic layer deposition” or “cyclical deposition” as used herein refers to the sequential introduction of two or more reactive compounds to deposit a layer of material on a substrate surface. The two, three, or more reactive compounds may alternatively be introduced into a reaction zone of a process chamber. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. During each time delay, a purge gas, such as nitrogen, is introduced into the process chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, introducing a purge gas, pulsing compound B and introducing a purge gas is a cycle. A cycle can start with either compound A or compound B and continue the respective order of the cycle until achieving a film with the desired thickness. In another embodiment, a first precursor containing compound A, a second precursor containing compound B, and a third precursor containing compound C are each separately pulsed into the process chamber. Alternatively, a pulse of a first precursor may overlap in time with a pulse of a second precursor while a pulse of a third precursor does not overlap in time with either pulse of the first and second precursors.

Experiments

The experiments in this section were conducted on substrates initially prepared by thermally growing a silicon dioxide layer with a thickness of 3,000 Å. Subsequently, a tantalum nitride layer was deposited by an ALD process with a thickness of about 10 Å. A full description of the deposition techniques are further discussed in commonly assigned U.S. Pat. No. 6,951,804, which is incorporated herein by reference in its entirety. The tantalum nitride film is a dielectric material with a sheet resistance greater than 20,000 Ω/sq.

The ALD experiments were completed in an ALD chamber, available from Applied Materials, Inc., located in Santa Clara, Calif. The chamber spacing (distance between the wafer and the top of chamber body) was about 230 mils (5.84 mm).

Experiment 1: (DMPD)₂Ru with constant flow of NH₃ and intermediate plasma—The ruthenium precursor used during this experiment was bis(2,4-dimethylpentadienyl) ruthenium ((DMPD)₂Ru). During the experiment, the pressure within the process chamber was maintained at about 2 Torr and the substrate was heated to about 300° C. The ALD cycle included the following steps. A ruthenium precursor gas was formed by passing a nitrogen carrier gas with a flow rate of about 500 sccm through an ampoule of (DMPD)₂Ru heated at a temperature of about 80° C. The substrate was exposed to the ruthenium precursor gas with a flow rate of about 500 sccm and ammonia gas with a flow rate of about 1,500 sccm for about 3 seconds. The flow of the ruthenium precursor gas was stopped while the flow of the ammonia gas was maintained during a purge step. The purge step was conducted for about 2 seconds. Subsequently, a plasma was ignited to form an ammonia plasma from the ammonia gas while maintaining the flow rate. The RF generator, having the power output set to about 125 watts at 13.56 MHz, produced the plasma for about 4 seconds during the plasma step. Thereafter, the plasma power was turned off and the chamber was exposed to a second purge step of ammonia gas with a constant flow rate for about 2 seconds. The deposition process was stopped after the repetition of about 140 ALD cycles. A layer of ruthenium material was deposited on the substrate with a thickness of about 5 Å. After analyzing the experimental data, it was determined that there was no existence of a nucleation delay, and the average deposition rate was about 0.22 Å/cycle.

Experiment 2: (MeCp)(EtCp)Ru with constant flow of NH₃ and intermediate plasma—The ruthenium precursor used during this experiment was methylcyclopentadienyl ethylcyclopentadienyl ruthenium ((MeCp)(EtCp)Ru). During the experiment, the pressure within the process chamber was maintained at about 2 Torr and the substrate was heated to about 300° C. The ALD cycle included the following steps. A ruthenium precursor gas was formed by passing a nitrogen carrier gas with a flow rate of about 500 sccm through an ampoule of (MeCp)(EtCp)Ru heated at a temperature of about 80° C. The substrate was exposed to the ruthenium precursor gas with a flow rate of about 500 sccm and ammonia gas with a flow rate of about 1,500 sccm for about 3 seconds. The flow of the ruthenium precursor gas was stopped while the flow of the ammonia gas was maintained during a purge step. The purge step was conducted for about 2 seconds. Subsequently, a plasma was ignited to form an ammonia plasma from the ammonia gas while maintaining the flow rate. The RF generator, having the power output set to about 125 watts at 13.56 MHz, produced the plasma for about 4 seconds during the plasma step. Thereafter, the plasma power was turned off and the chamber was exposed to a second purge step of ammonia gas with a constant flow rate for about 2 seconds. The deposition process was stopped after the repetition of about 140 ALD cycles. A layer of ruthenium material was deposited on the substrate with a thickness of about 6 Å. After analyzing the experimental data, it was determined that a nucleation delay existed.

Experiment 3: (MeCp)(Py)Ru with constant flow of NH₃ and intermediate plasma—The ruthenium precursor used during this experiment was methylcyclopentadienyl pyrrolyl ruthenium ((MeCp)(Py)Ru). During the experiment, the pressure within the process chamber was maintained at about 2 Torr and the substrate was heated to about 300° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm and ammonia gas with a flow rate of about 1,500 sccm for about 3 seconds. The flow of the ruthenium precursor gas was stopped while the flow of the ammonia gas was maintained during a purge step. The purge step was conducted for about 2 seconds. Subsequently, a plasma was ignited to form an ammonia plasma from the ammonia gas while maintaining the flow rate. The RF generator, having the power output set to about 300 watts at 13.56 MHz, produced the plasma for about 4 seconds during the plasma step. Thereafter, the plasma power was turned off and the chamber was exposed to a second purge step of ammonia gas with a constant flow rate for about 2 seconds. The deposition process was stopped after the repetition of about 140 ALD cycles. A layer of ruthenium material was deposited on the substrate with a thickness of about 49 Å. After analyzing the experimental data, it was determined that there was no existence of a nucleation delay, and the average deposition rate was about 0.35 Å/cycle.

Experiment 4: (MeCp)(Py)Ru with constant flow of N₂ and intermediate plasma—During the experiment, the pressure within the process chamber was maintained at about 4 Torr and the substrate was heated to about 350° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm and nitrogen gas with a flow rate of about 1,500 sccm for about 3 seconds. The flow of the ruthenium precursor gas was stopped while the flow of the nitrogen gas was maintained during a purge step. The purge step was conducted for about 2 seconds. Subsequently, a plasma was ignited to form a nitrogen plasma from nitrogen gas while maintaining the flow rate. The RF generator, having the power output set to about 500 watts at 13.56 MHz, produced the plasma for about 4 seconds during the plasma step. Thereafter, the plasma power was turned off and the chamber was exposed to a second purge step of the nitrogen gas with a constant flow rate for about 2 seconds. The deposition process was stopped after the repetition of about 140 ALD cycles. A layer of ruthenium material was deposited on the substrate with a thickness of about 46 Å. After analyzing the experimental data, it was determined that there was no existence of a nucleation delay, and the average deposition rate was about 0.33 Å/cycle.

Experiment 5: (MeCp)(Py)Ru with constant flow of H₂ and intermediate plasma—During the experiment, the pressure within the process chamber was maintained at about 4 Torr and the substrate was heated to about 350° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm and hydrogen gas with a flow rate of about 1,500 sccm for about 3 seconds. The flow of the ruthenium precursor gas was stopped while the flow of the hydrogen gas was maintained during a purge step. The purge step was conducted for about 2 seconds. Subsequently, a plasma was ignited to form a hydrogen plasma from the hydrogen gas while maintaining the flow rate. The RF generator, having the power output set to about 500 watts at 13.56 MHz, produced the plasma for about 4 seconds during the plasma step. Thereafter, the plasma power was turned off and the chamber was exposed to a second purge step of hydrogen gas with a constant flow rate for about 2 seconds. The deposition process was stopped after the repetition of about 140 ALD cycles. A layer of ruthenium material was deposited on the substrate with a thickness of about 45 Å. After analyzing the experimental data, it was determined that there was no existence of a nucleation delay, and the average deposition rate was about 0.32 Å/cycle.

Experiment 6: (MeCp)(Py)Ru with intermediate NH₃ plasma—During the experiment, the pressure within the process chamber was maintained at about 2 Torr and the substrate was heated to about 300° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm for about 3 seconds. The flow of the ruthenium precursor gas was stopped and a nitrogen purge gas with a flow rate of about 500 sccm was administered into the chamber during a purge step. The purge step was conducted for about 2 seconds. Thereafter, an ammonia gas with a flow rate of about 1,500 sccm was administered into the chamber after stopping the flow of the nitrogen gas. Subsequently, a plasma was ignited to form an ammonia plasma from the ammonia gas while maintaining the flow rate. The RF generator, having the power output set to about 300 watts at 13.56 MHz, produced the plasma for about 4 seconds during the plasma step. Thereafter, the flow of the ammonia gas and the plasma power were turned off. The chamber was exposed to a second purge step of nitrogen gas with a flow rate of about 500 sccm for about 2 seconds. The deposition process was stopped after the repetition of about 150 ALD cycles. A layer of ruthenium material was deposited on the substrate with a thickness of about 51 Å. After analyzing the experimental data, it was determined that there was no existence of a nucleation delay, and the average deposition rate was about 0.34 Å/cycle.

Experiment 7: (MeCp)(Py)Ru with intermediate N₂ plasma—During the experiment, the pressure within the process chamber was maintained at about 4 Torr and the substrate was heated to about 350° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm for about 3 seconds. The flow of the ruthenium precursor gas was stopped and a nitrogen purge gas with a flow rate of about 500 sccm was administered into the chamber during a purge step. The purge step was conducted for about 2 seconds. Subsequently, a plasma was ignited to form a nitrogen plasma from the nitrogen gas while maintaining the flow rate. The RF generator, having the power output set to about 500 watts at 13.56 MHz, produced the plasma for about 4 seconds during the plasma step. Thereafter, the flow of the nitrogen gas and the plasma power were turned off. The chamber was exposed to a second purge step of nitrogen gas with a flow rate of about 500 sccm for about 2 seconds. The deposition process was stopped after the repetition of about 150 ALD cycles. A layer of ruthenium material was deposited on the substrate with a thickness of about 50 Å. After analyzing the experimental data, it was determined that there was no existence of a nucleation delay, and the average deposition rate was about 0.33 Å/cycle.

Experiment 8: (MeCp)(Py)Ru with intermediate H₂ plasma—During the experiment, the pressure within the process chamber was maintained at about 4 Torr and the substrate was heated to about 350° C. The ALD cycle included the following steps. A ruthenium precursor gas was formed by passing a nitrogen carrier gas with a flow rate of about 500 sccm through an ampoule of (MeCp)(Py)Ru heated at a temperature of about 80° C. The substrate was exposed to the ruthenium precursor gas with a flow rate of about 500 sccm for about 3 seconds. The flow of the ruthenium precursor gas was stopped and a nitrogen purge gas with a flow rate of about 500 sccm was administered into the chamber during a purge step. The purge step was conducted for about 2 seconds. Thereafter, a hydrogen gas with a flow rate of about 1,500 sccm was administered into the chamber after stopping the flow of the nitrogen gas. Subsequently, a plasma was ignited to form a hydrogen plasma from the hydrogen gas while maintaining the flow rate. The RF generator, having the power output set to about 500 watts at 13.56 MHz, produced the plasma for about 4 seconds during the plasma step. Thereafter, the flow of the hydrogen gas and the plasma power were turned off. The chamber was exposed to a second purge step of nitrogen gas with a flow rate of about 500 sccm for about 2 seconds. The deposition process was stopped after the repetition of about 150 ALD cycles. A layer of ruthenium material was deposited on the substrate with a thickness of about 48 Å. After analyzing the experimental data, it was determined that there was no existence of a nucleation delay, and the average deposition rate was about 0.32 Å/cycle.

While foregoing is directed to the preferred embodiment of the invention other and further embodiments of the invention may be devised without departing from the basic scope thereof, and the scope thereof is determined by the claims that follow.

1. A method for forming a ruthenium material on a substrate, comprising:
positioning a substrate within a process chamber; and
exposing the substrate sequentially to a reagent and a pyrrolyl ruthenium precursor to form a ruthenium material on the substrate during an atomic layer deposition process.

2. The method of claim 1, wherein the pyrrolyl ruthenium precursor comprises at least one pyrrolyl ligand with the chemical formula of: 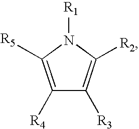
wherein R₁, R₂, R₃, R₄, and R₅ are each independently absent or selected from the group consisting of hydrogen, methyl, ethyl, propyl, butyl, amyl, derivatives thereof, and combinations thereof.

3. The method of claim 2, wherein R₁ is absent and each R₂, R₃, R₄, or R₅ is independently hydrogen or methyl.

4. The method of claim 2, wherein R₁ is absent and each R₂ or R₅ is independently methyl or ethyl.

5. The method of claim 1, wherein the pyrrolyl ruthenium precursor comprises a first pyrrolyl ligand and a second pyrrolyl ligand.

6. The method of claim 5, wherein the first pyrrolyl ligand is different than the second pyrrolyl ligand.

7. The method of claim 5, wherein the first and second pyrrolyl ligands are the same.

8. The method of claim 1, wherein the pyrrolyl ruthenium precursor comprises a first pyrrolyl ligand and a dienyl ligand.

9. The method of claim 8, wherein the pyrrolyl ruthenium precursor is selected from the group consisting of pentadienyl pyrrolyl ruthenium, cyclopentadienyl pyrrolyl ruthenium, alkylpentadienyl pyrrolyl ruthenium, alkylcyclopentadienyl pyrrolyl ruthenium and derivatives thereof.

10. The method of claim 1, wherein the pyrrolyl ruthenium precursor is selected from the group consisting of alkyl pyrrolyl ruthenium, bis(pyrrolyl) ruthenium, dienyl pyrrolyl ruthenium, and derivatives thereof.

11. The method of claim 1, wherein the pyrrolyl ruthenium precursor is selected from the group consisting of bis(tetramethylpyrrolyl) ruthenium, bis(2,5-dimethylpyrrolyl) ruthenium, bis(2,5-diethylpyrrolyl) ruthenium, bis(tetraethylpyrrolyl) ruthenium, pentadienyl tetramethylpyrrolyl ruthenium, pentadienyl 2,5-dimethylpyrrolyl ruthenium pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium, and derivatives thereof.

12. The method of claim 1, wherein a plasma is ignited during the atomic layer deposition process.

13. The method of claim 12, wherein a plasma is generated by a radio frequency generator.

14. The method of claim 12, wherein the reagent comprises an ammonia plasma.

15. The method of claim 12, wherein the reagent comprises a nitrogen plasma.

16. The method of claim 12, wherein the reagent comprises a hydrogen plasma.

17. The method of claim 1, wherein the ruthenium material is deposited during a thermal atomic layer deposition process.

18. The method of claim 17, wherein the reagent comprises a compound selected from the group consisting of hydrogen, ammonia, hydrazine, silane, disilane, diborane, triethylborane, derivatives thereof, and combinations thereof.

19. The method of claim 18, wherein the substrate is heated to a temperature within a range from about 150° C. to about 400° C. during the atomic layer deposition process.

20. The method of claim 1, wherein the ruthenium material is deposited on a barrier layer disposed on the substrate and the barrier layer comprises a material selected from the group consisting of tantalum, tantalum nitride, tantalum silicon nitride, titanium, titanium nitride, titanium silicon nitride, tungsten, tungsten nitride, derivatives thereof, and combinations thereof.

21. The method of claim 1, wherein the ruthenium material is deposited on a dielectric material comprising a material selected from the group consisting of silicon dioxide, silicon nitride, silicon oxynitride, carbon-doped silicon oxides, tantalum oxide, titanium oxide, boron strontium titanate, hafnium oxide, hafnium silicate, derivatives thereof, and combinations thereof.

22. The method of claim 1, wherein a conductive metal is deposited on the ruthenium material.

23. The method of claim 22, wherein the conductive material is selected from the group consisting of copper, tungsten, aluminum, alloys thereof, and combinations thereof.

24. The method of claim 23, wherein the conductive metal comprises a seed layer and a bulk layer.

25. The method of claim 24, wherein the seed layer and the bulk layer each comprise copper.

26. The method of claim 25, wherein the seed layer is formed by an electroless deposition process, an electroplating process, or a physical vapor deposition process.

27. The method of claim 26, wherein the bulk layer is formed by an electroless deposition process, an electroplating process, or a chemical vapor deposition process.

28. The method of claim 24, wherein the seed layer and the bulk layer each comprise tungsten.

29. The method of claim 28, wherein the seed layer is formed by an atomic layer deposition process or a physical vapor deposition process.

30. The method of claim 29, wherein the bulk layer is formed by a physical vapor deposition process or a chemical vapor deposition process.

31. A method for forming a ruthenium material on a substrate, comprising:
positioning a substrate within a process chamber;
exposing the substrate to a pyrrolyl ruthenium precursor to form a ruthenium-containing layer on the substrate;
purging the process chamber with a purge gas;
exposing the substrate to a reagent to form a ruthenium material thereon; and
purging the process chamber with the purge gas.

32. The method of claim 31, wherein a plasma is ignited while exposing the substrate to the reagent.

33. The method of claim 32, wherein the reagent comprises an ammonia plasma.

34. The method of claim 32, wherein the reagent comprises a nitrogen plasma.

35. The method of claim 32, wherein the reagent comprises a hydrogen plasma.

36. The method of claim 32, wherein the pyrrolyl ruthenium precursor comprises at least one pyrrolyl ligand with the chemical formula of: 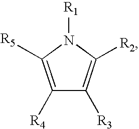
wherein R₁, R₂, R₃, R₄, and R₅ are each independently absent or selected from the group consisting of hydrogen, methyl, ethyl, propyl, butyl, amyl, derivatives thereof, and combinations thereof.

37. The method of claim 36, wherein R₁ is absent and each R₂, R₃, R₄, or R₅ is independently hydrogen or methyl.

38. The method of claim 36, wherein R₁ is absent and each R₂ or R₅ is independently methyl or ethyl.

39. The method of claim 32, wherein the pyrrolyl ruthenium precursor is selected from the group consisting of bis(tetramethylpyrrolyl) ruthenium, bis(2,5-dimethylpyrrolyl) ruthenium, bis(2,5-diethylpyrrolyl) ruthenium, bis(tetraethylpyrrolyl) ruthenium pentadienyl tetramethylpyrrolyl ruthenium, pentadienyl 2,5-dimethylpyrrolyl ruthenium, pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium, methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium, derivatives thereof, and combinations thereof.

40. The method of claim 31, wherein the ruthenium material is deposited during a thermal atomic layer deposition process.

41. The method of claim 40, wherein the pyrrolyl ruthenium precursor is selected from the group consisting of bis(tetramethylpyrrolyl) ruthenium, bis(2,5-dimethylpyrrolyl) ruthenium, bis(2,5-diethylpyrrolyl) ruthenium, bis(tetraethylpyrrolyl) ruthenium pentadienyl tetramethylpyrrolyl ruthenium, pentadienyl 2,5-dimethylpyrrolyl ruthenium, pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium, methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium, derivatives thereof, and combinations thereof.

42. The method of claim 41, wherein the reagent comprises a compound selected from the group consisting of hydrogen, ammonia, hydrazine, silane, disilane, diborane, trimethylborane, triethylborane, derivatives thereof, and combinations thereof.

43. A method for forming a ruthenium material on a substrate, comprising:
positioning a substrate containing a dielectric material within a process chamber; and
exposing the substrate sequentially to a reagent and a pyrrolyl ruthenium precursor to form a ruthenium material on the dielectric material during an atomic layer deposition process.

44. The method of claim 43, wherein the dielectric material comprises a material selected from the group consisting of silicon dioxide, silicon nitride, silicon oxynitride, carbon-doped silicon oxides, tantalum oxide, titanium oxide, boron strontium titanate, hafnium oxide, hafnium silicate, derivatives thereof, and combinations thereof.

45. A method for forming a ruthenium material on a substrate, comprising:
positioning a substrate within a process chamber; and
exposing the substrate sequentially to a reagent and a pyrrolyl ruthenium precursor to form a ruthenium material on the substrate during an atomic layer deposition process, wherein the pyrrolyl ruthenium precursor is selected from the group consisting of bis(tetramethylpyrrolyl) ruthenium, bis(2,5-dimethylpyrrolyl) ruthenium, bis(2,5-diethylpyrrolyl) ruthenium, bis(tetraethylpyrrolyl) ruthenium, pentadienyl tetramethylpyrrolyl ruthenium, pentadienyl 2,5-dimethylpyrrolyl ruthenium, pentadienyl tetraethylpyrrolyl ruthenium, pentadienyl 2,5-diethylpyrrolyl ruthenium, 1,3-dimethylpentadienyl pyrrolyl ruthenium, 1,3-diethylpentadienyl pyrrolyl ruthenium, methylcyclopentadienyl pyrrolyl ruthenium, ethylcyclopentadienyl pyrrolyl ruthenium, 2-methylpyrrolyl pyrrolyl ruthenium, 2-ethylpyrrolyl pyrrolyl ruthenium, derivatives thereof, and combinations thereof.
